(19) United States
(12) Patent Application Publication
(10) Pub. No.: US 2026/0186693 A1
(43) Pub. Date: Jul. 2, 2026

(54) REFRESH TRIGGERS TO STABILIZE READ OPERATION PERFORMANCE

(71) Applicant: Micron Technology, Inc., Boise, ID (US)

(72) Inventors: Nicola Colella, Capodrise (IT); Pierluigi Manzo, Napoli (IT); Alessandro Magnavacca, Sesto San Giovanni (IT); Ciro Feliciano, Casandrino (IT); Michela Spagnolo, Sesto San Giovanni (IT); Antonio Ammendola, San Sebastiano al Vesuvio (IT); Stefano Falduti, Vimercate (IT)

(21) Appl. No.: 19/410,983

(22) Filed: Dec. 5, 2025

Related U.S. Application Data
(60) Provisional application No. 63/739,048, filed on Dec. 26, 2024.

(51) Int. Cl. G06F 3/06

(52) U.S. Cl. CPC G06F 3/0655; G06F 3/0604; G06F 3/0679

(57) ABSTRACT

Methods, systems, and devices for refresh triggers to stabilize read operation performance are described. A memory system may implement the use of a read amplification factor (RAF) to estimate a rate between an actual quantity of read operations performed and an ideal quantity of read operations used to complete read commands. A memory system may determine an RAF for a range of memory addresses. The memory system may update one or more status indicators associated with the RAF. Based on the status indicators, the memory system may modify a frequency of performing refresh operations on the range of memory addresses to better account for the state of the memory addresses. For example, the memory system may determine that the frequency at which the memory system performs refresh operations may be increased, while in other examples it may be decreased.

### CROSS REFERENCE

The present Application for Patent claims priority to U.S. Patent Application No. 63/739,048 by Colella et al., entitled “REFRESH TRIGGERS TO STABILIZE READ OPERATION PERFORMANCE,” filed Dec. 26, 2024, which is assigned to the assignee hereof, and which is expressly incorporated by reference in its entirety herein.

### TECHNICAL FIELD

The following relates to one or more systems for memory, including refresh triggers to stabilize read operation performance.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not- or (NOR) and not- and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports refresh triggers to stabilize read operation performance in accordance with examples as disclosed herein.

FIG. 2 shows an example of a system that supports refresh triggers to stabilize read operation performance in accordance with examples as disclosed herein.

FIG. 3 shows an example of a performance graph that supports refresh triggers to stabilize read operation performance in accordance with examples as disclosed herein.

FIGS. 4 through 6 show examples of process flows that support refresh triggers to stabilize read operation performance in accordance with examples as disclosed herein.

FIG. 7 shows a block diagram of a host system that supports refresh triggers to stabilize read operation performance in accordance with examples as disclosed herein.

FIG. 8 shows a block diagram of a memory system that supports refresh triggers to stabilize read operation performance in accordance with examples as disclosed herein.

FIGS. 9 through 11 show flowcharts illustrating a method or methods that support refresh triggers to stabilize read operation performance in accordance with examples as disclosed herein.

### DETAILED DESCRIPTION

Some memory systems may begin to wear out after extended usage. In the case a memory system may start to wear out, memory blocks of the memory system may not be able to retain correct data at the same rate as memory blocks of a new memory system. One way to account for errors in memory cells may be to perform refresh operations to stabilize the performance of read operations. In response to errors being present in data being read, some memory systems may implement a series of error mitigation techniques. One such technique may include a read retry where the memory cells are read again and compared with a different reference voltage. In some cases, as the quantity of errors increases, a quantity of read retries increases, and thus the quantity of read operations performed by the memory system in response to a quantity of read commands may increase. As the memory system performs additional read retries, the performance of the memory system may be reduced. Additionally, in the case that one or more memory blocks may be worn (e.g., marginal), read performance of the memory system may be unstable until the refresh is triggered. In some examples, the memory system may be enabled to trigger a refresh to address reliability issues of the memory system. However, in some examples, refresh operations may not be triggered dynamically, or the rates of refresh operations may be fixed. Thus, the performance of the memory system may remain unsatisfactory due to the marginal blocks for an extended time until a refresh operation is performed.

Techniques are described here for triggering refresh operations and/or adjusting refresh rates based on a performance impact to the memory system. A memory system may implement the use of a read amplification factor (RAF) to estimate a rate between an actual quantity of read operations performed and an ideal (e.g., or theoretical) quantity of read operations used to complete read commands. The actual quantity of read operation performed for a read command may be greater than one due to read retries procedures where additional read operations are performed in response to the same read command. In some examples, a memory system may determine an RAF for a range of memory addresses. In some examples, the memory system may determine the RAF in response to a command from a host system, while in other examples the memory system may determine the RAF without a command. The memory system may update one or more status indicators associated with the RAF. Based on the status indicators, the memory system may determine a priority of refresh operations associated with a range of memory addresses and modify a frequency of performing the refresh operations on the range of memory addresses to better account for the state of the memory addresses. That is, in some examples the memory system may determine, via comparing the RAF to one or more thresholds, that the frequency at which the memory system performs refresh operations may be increased, while in other examples it may be decreased (e.g., refresh operations may not be performed, refresh operations may be performed during a background operation, refresh operations may be performed during a write operation and during a background operation, refresh operations may be performed also during a read operation). The use of an RAF may allow the memory system to adjust refresh operations based on current performance of the memory system, may enable the memory system to address errors in memory blocks while reducing a decrease in read operation performance. For example, by triggering and modulating a rate of refreshes according to performance impact based on the RAF, the memory system may take read attempts, idle time, and performance expectations into account.

In addition to applicability in memory systems as described herein, refresh triggers to stabilize read operation performance may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving memory access speeds, which may decrease processing or latency times, improve response times, or otherwise improve user experience, among other benefits.

In addition to applicability in memory systems as described herein, refresh triggers to stabilize read operation performance may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by decreasing address memory block instability issues, which may extend the life of electronic devices and thereby reduce electronic waste, among other benefits.

Features of the disclosure are illustrated and described in the context of systems, devices, and circuits. Features of the disclosure are further illustrated and described in the context of performance graphs, process flows, and flowcharts.

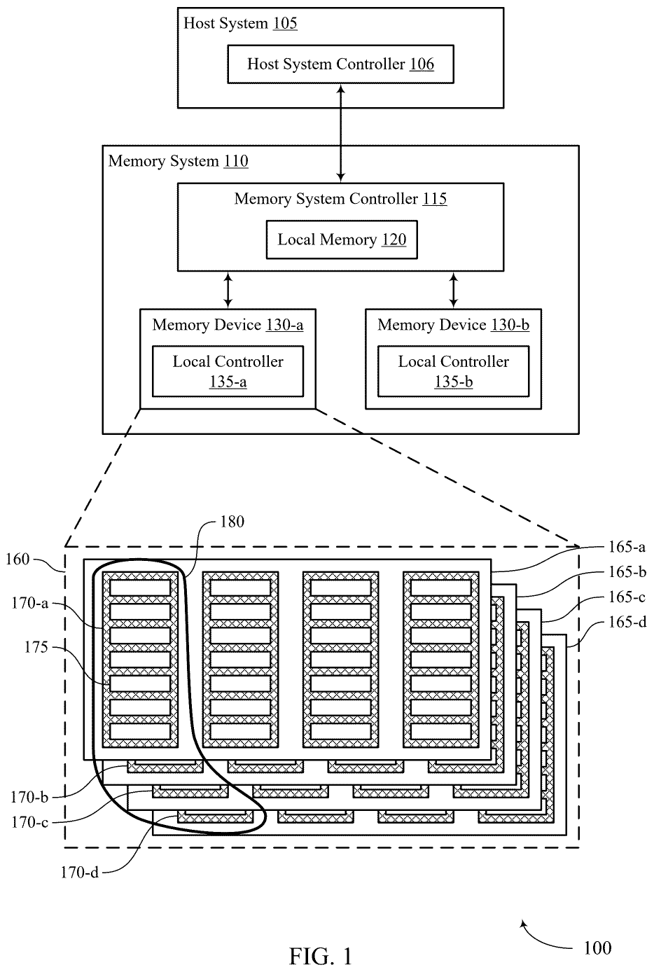

FIG. 1 shows an example of a system 100 that supports refresh triggers to stabilize read operation performance in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b. A local controller 135 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new, valid block 170 rather than the old, invalid block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by the local controller 135 or memory system controller 115.

In some cases, L2P mapping tables may be maintained, and data may be marked as valid or invalid at the page level of granularity, and a page 175 may contain valid data, invalid data, or no data. Invalid data may be data that is outdated, which may be due to a more recent or updated version of the data being stored in a different page 175 of the memory device 130. Invalid data may have been previously programmed to the invalid page 175 but may no longer be associated with a valid logical address, such as a logical address referenced by the host system 105. Valid data may be the most recent version of such data being stored on the memory device 130. A page 175 that includes no data may be a page 175 that has never been written to or that has been erased.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

The memory system 110 may begin to wear out after extended usage. In the case the memory system 110 may start to wear out, memory blocks 170 of the memory system 110 may not be able to retain correct data at the same rate as memory blocks 170 of a new memory system 110. One way to account for errors in memory cells may be to perform refresh operations on pages of the worn memory blocks 170 to stabilize the performance of read operations on the worn memory blocks 170. In response to errors being present in data being read, some memory systems 110 may implement a series of error mitigation techniques. One such technique may include a read retry where the memory cells are read again and compared with a different reference voltage. In some cases, as the quantity of errors increases, a quantity of read retries increases, and thus the quantity of read operations performed by the memory system 110 in response to a quantity of read commands may increase. As the memory system performs additional read retries, performance of the memory system 110 may be reduced. Additionally, in the case that one or more memory blocks may be worn (e.g., marginal), read performance of the memory system 110 may be unstable until the refresh is triggered. In some examples, the memory system 110 may be enabled to trigger a refresh to address reliability issues of the memory system 110. However, in some examples, refresh operations may not be triggered dynamically or the rates of refresh operations may be fixed. Thus, the performance of the memory system 110 may remain unsatisfactory due to the marginal blocks 170 for an extended time until a refresh operation is performed.

Techniques are described here for triggering refresh operations and/or adjusting refresh rates based on a performance impact to the memory system. A memory system 110 may implement the use of an RAF to estimate a rate between an actual quantity of read operations performed and an ideal (e.g., or theoretical) quantity of read operations used to complete read commands. The actual quantity of read operation performed for a read command may be greater than one due to read retries procedures where additional read operations are performed in response to the same read command. In some examples, the memory system 110 may determine an RAF for a range of memory addresses. In some examples, the memory system 110 may determine the RAF in response to a command from a host system 105, while in other examples the memory system 110 may determine the RAF without a command. The memory system 110 may update one or more status indicators associated with the RAF. Based on the status indicators, the memory system 110 may modify a frequency of performing refresh operations on the range of memory addresses to better account for the state of the memory addresses. That is, in some examples the memory system 110 may determine, via comparing the RAF to one or more thresholds, that the frequency at which the memory system 110 performs refresh operations may be increased, while in other examples it may be decreased. The use of an RAF may allow the memory system 110 to adjust refresh operations based on current performance of the memory system 110, may enable the memory system 110 to address errors in memory blocks while reducing a decrease in read operation performance. For example, by triggering and modulating a rate of refreshes according to performance impact based on the RAF, the memory system 110 may take read attempts, idle time, and performance expectations into account.

The system 100 may include any quantity of non-transitory computer readable media that support refresh triggers to stabilize read operation performance. For example, the host system 105 (e.g., a host system controller 106), the memory system 110 (e.g., a memory system controller 115), or a memory device 130 (e.g., a local controller 135), or any combination thereof may include or otherwise may access one or more non-transitory computer readable media storing instructions (e.g., firmware, logic, code) for performing the functions ascribed herein to the host system 105, the memory system 110, or the memory device 130, or combination thereof. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

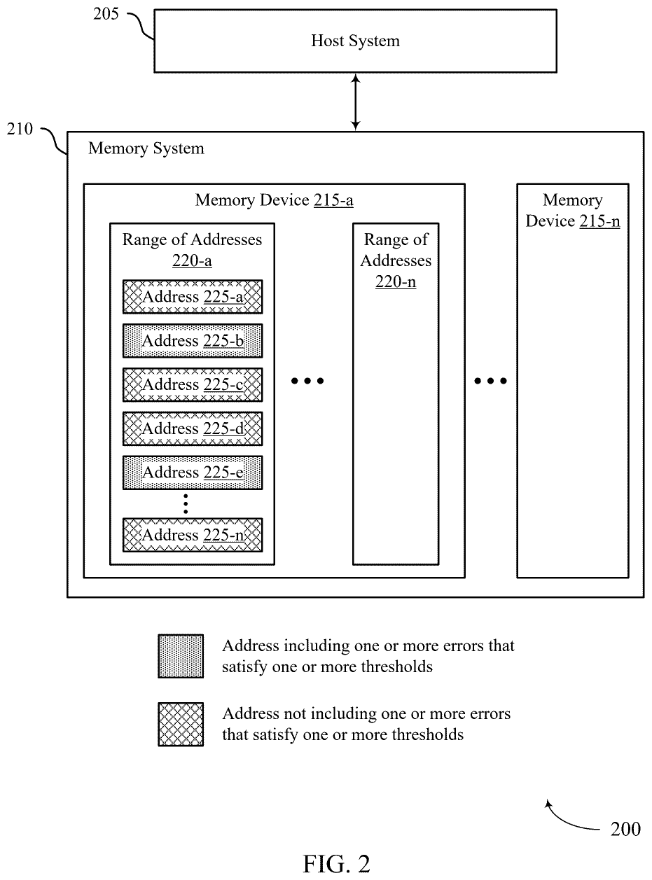

FIG. 2 shows an example of a system 200 that supports refresh triggers to stabilize read operation performance in accordance with examples as disclosed herein. The system 200 may be an example of a system 100 as described with reference to FIG. 1, or aspects thereof. The system 200 may include a memory system 210 configured to store data received from the host system 205 and to send data to the host system 205, if requested by the host system 205 using access commands (e.g., read commands or write commands). The system 200 may implement aspects of the system 100 as described with reference to FIG. 1. For example, the memory system 210 and the host system 205 may be examples of the memory system 110 and the host system 105, respectively.

The memory system 210 may include one or more memory devices 215. The memory devices 215 may be examples of the memory devices 130 as described with reference to FIG. 1. Each of the memory devices 215 may include a range of addresses 220 that may each include one or more addresses 225. In some examples, the range of addresses 220 may be an example of one or more memory blocks 170 and the addresses may be examples of pages 175 as described with reference to FIG. 1. In some examples, within the memory device 215-a, the range of addresses 220-a may include one or more addresses 225 including one or more errors that satisfy one or more thresholds (e.g., erroneous data) and may include one or more addresses 225 that do not include one or more errors that satisfy the one or more thresholds. Each of the rest of the ranges of addresses 220 may also include various combinations of the addresses 225 (e.g., not illustrated).

The memory device 215 (e.g., the addresses 225 of the memory devices 215) may begin to wear out after extended usage. For example, each time the memory system 210 accesses the addresses 225 of the memory devices 215, the material of the memory devices 215 may be negatively impacted. With extended use, a memory device 215 may begin to wear out and the addresses 225 may become unable to retain correct data at the same rate as addresses 225 of a new (e.g., unused, unaccessed) memory device 215. For example, when error correction codes (ECCs) associated with data read from the marginal addresses 225 are compared with expected ECCs, the ECCs may not be the same-which may indicate errors in the data. To stabilize the performance of access operations on the memory device 215 (e.g., the addresses 225), the memory system 210 may perform refresh operations on the addresses 225. In some examples, the memory system 210 may increase a rate of performing refresh operations on an address 225 that has begun to wear out, which may decrease the performance the memory system 210 by taking additional time for background operations (such as refresh operations).

In response to errors being present in data being read from the addresses 225, the memory system 210 may implement a series of error mitigation techniques. One such technique may include a read-retry operation where the addresses 225 are re-read and compared with a different reference voltage. Read retry techniques may include one or more read retries in response to a single read command (depending on the errors present in each read retry). Therefore, as the quantity of errors increases (e.g., and a quantity of read retries increases), the quantity of read operations by the memory system 210 may increase and the performance of the memory system 210 may be further reduced by the increase quantity of accesses of the addresses 225. The memory system 210 may use other techniques to account for errors, but these other techniques may not account for usage and expectation tradeoffs for each of the memory devices 215. Additionally, in the case that one or more addresses 225 may be worn (e.g., marginal), read performance of the memory system 210 may be unstable. In some examples, the memory system 210 may be enabled to trigger a refresh to address reliability issues of the memory system 210. However, in some examples, there dynamically triggering refresh operations and/or adjusting a refresh rate may not be possible. In such cases, the memory system 210 performance may continue to degrade.

To account for performance impact associated with read refresh operations, the memory system 210 may implement the use of an RAF to estimate a rate between an actual quantity of read operations performed on the range of addresses 220 and an ideal (e.g., or theoretical) quantity of read operations used to complete read commands on the range of addresses 220 (e.g., a quantity associated with read operations on a range of addresses 220 that may not be worn). The memory system 210 may compare the RAF to one or more thresholds and may determine a frequency of refresh operations to use for the associated range of addresses 220. The use of an RAF may allow the memory system 210 to adjust refresh rates at a memory system based on changing conditions at the memory system 210 (e.g., portions of the memory system are wearing out).

The memory system 210 may determine (e.g., calculate, generate) an RAF for each of the ranges of addresses 220. Each RAF may be an example of a rate between an actual quantity and theoretical quantity of read operations for performing read operations at a respective range of addresses 220, as described by the Equation 1.

$$RAF = \frac{real read count}{ideal read count} \qquad ( 1 )$$

The memory system 210 may keep count of read attempts, read retries, and other read operations for a range of addresses 220 and use this as the “real read count,” and may estimate an “ideal read count” for the same range of addresses 220. In some cases, an ideal read count for a single read command may be a single (e.g., meaning one) read operation performed in response to the read command. In some examples, the memory system 210 may add additional “counts” to the real read count to account for other error handling operations (e.g., according to one or more read error handling (REH) steps). For example, if the memory system performs one or more read retries in response to errors found in the data read, then the real read count may be higher than the ideal read count. High quantities of errors on a page are associated with a large RAF value. In some examples, in the case that a size of a single read operation may be 96k bytes and the host system 205 may request to read 512k bytes of data, the memory system 210 may determine the ideal read count to be approximately 6 (e.g., 512/96). The memory system 210 may determine that each 4k chunk of data included in the range of addresses 220-a may need correction, and thus may determine the real read count of the range of addresses 220 to be 132 (e.g., 6+512/4=132). The memory system 210 may determine, using the RAF equation described herein, the RAF associated with the range of addresses 220-a to be 22 (e.g., 132/6=22). In the case the memory system 210 may determine a large RAF value, the memory system 210 may determine that an increase of the frequency of refresh operations on the range of addresses 220 may be useful to reduce the quantity of errors and thus reduce the RAF on future read commands.

The memory system 210 may compare the RAF associated with the range of addresses 220 to one or more thresholds and may increase or decrease the frequency of refresh operations on the range of addresses 220 based on the result to increase overall read performance stability of the memory system 210. For example, the memory system 210 may determine the RAF to be less than a first threshold (e.g., less than all thresholds), which may indicate that a refresh may not be required. In other examples, the memory system 210 may determine the RAF to be greater than the first threshold and less than a second threshold (e.g., between the first and second thresholds), which may indicate that a refresh may not be urgent and the memory system 210 may execute the refreshes during a background operation. In other examples, the memory system 210 may determine the RAF to be greater than the second threshold and less than a third threshold (e.g., between the second and third thresholds), which may indicate that a refresh may negatively impact the performance of the memory system 210 and the memory system 210 may interpret some frontend operation (e.g., a write operation) to execute the refresh operations. In other examples, the memory system 210 may determine the RAF to be greater than the third threshold (e.g., greater than all thresholds), which may indicate that a refresh may be urgent due to high performance impact and the memory system may allocate resources to perform the refresh operations immediately. The thresholds may be used to determine a priority for performing a refresh operation on a set of memory addresses. Depending on the priority, the memory system may implement different procedures to perform the refresh operations with faster or slower latency.

Based on comparing the RAF to the one or more thresholds, the memory system 210 may update one or more status indicators. The memory system 210 may set one or more bits to indicate the result of comparing the RAF to the thresholds. For example, the memory system 210 may set “00” to indicate a lowest priority for refreshing (e.g., that a refresh may not be required), “01” to indicate a lower priority for refreshing (e.g., that the memory system 210 may execute the refreshes during a background operation), “10” to indicate a higher priority for refreshing (e.g., that the memory system 210 may execute the refresh operations during some operations such as write operations), and “11” to indicate a highest priority for refreshing (e.g., that the memory system 210 may immediately perform the refresh operations and interrupt various frontend operations). In some examples, the memory system 210 may communicate the updated status indicators to the host system 205 and the host system 205 may initiate the refresh operations on the range of addresses 220. In other examples, the memory system 210 may use the updated status indicators to perform the refresh operations on the range of addresses 220 (e.g., the memory system may perform one or more refresh operations without receiving commands from the host).

The system 200 may use one or more modes to perform the refresh operations. For example, the system 200 may implement a “host controlled mode” where the host system 205 controls the refresh operations. The host system 205 may transmit (e.g., output, communicate) a command to the memory system 210 requesting indication that the memory system 210 supports use of an RAF. In the case that the memory system 210 may indicate that the memory system 210 does not support the use of an RAF, the host system 205 may use traditional refresh operation techniques. In the case that the memory system 210 may indicate that the memory system 210 does support the use of an RAF, however, the host system 205 may send a command specifying a range of addresses 220 at the memory system 210. In some examples, the command may also include a quantity of ranges of addresses 220 and a size of each range of addresses 220. Additionally, or alternatively, the range of addresses 220 may include addresses 225 from multiple memory devices 215 or across multiple virtual memory blocks (e.g., not illustrated).

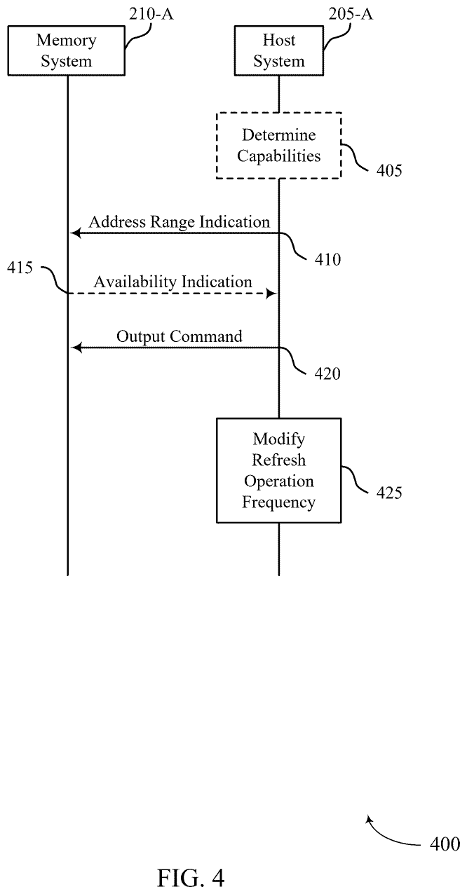

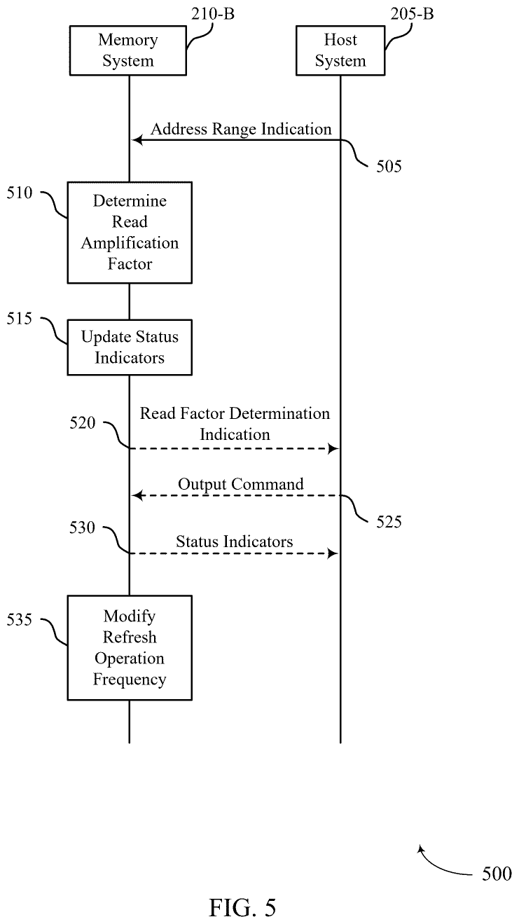

In response to the command, the memory system 210 may calculate an RAF for each range of addresses 220 indicated in the command as further described herein. The memory system 210 may compare the RAF to one or more thresholds and may update one or more status indicators at the memory system 210 according to the RAF. In some examples, the memory system 210 may also transmit an indication to the host system 205 informing the host system 205 that the RAF is calculated. After the RAF is calculated, the host system 205 may communicate a command to the memory system 210 requesting one or more of the updated status indicators associated with the range of addresses 220 (e.g., associated with the RAF). The memory system 210 may transmit the one or more updated status indicators to the host system 205, and the host system 205 may use the updated status indicators to modify a frequency of the refresh operations at the memory system (e.g., as further described with reference to FIG. 4). In some cases, the host system 205 may provide idle time at the memory system 210 during which the memory system 210 may perform the refresh operation. In other cases, the host system 205 may transmit a command for the memory system 210 to perform the refresh operations. In some other cases, the host system 205 may allow the memory system 210 to complete the refresh operations without host interference or commands (e.g., as further described with reference to FIG. 5). In some examples, at least one of RAFs, thresholds, and/or one or more status indicators may be stored in mode registers of the memory system. In some cases, the mode registers may be configured with read/write access for the memory system and read/write access for the host system. In some cases, the mode registers may be configured with read/write access for the memory system and read access for the host system. In some cases, a first set of the mode registers may be configured with read/write access for the memory system and read-only access for the host system and a second set of the mode registers may be configured read-only access for the memory system and read/write access for the host system.

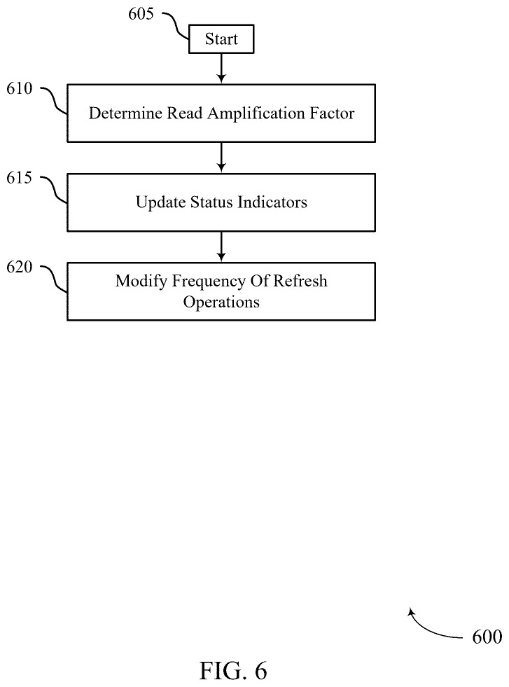

The system 200 may implement a “device controlled mode” where the memory system 210 controls the refresh operations. For example, when a read command is received at the memory system 210 from the host system 205, the memory system 210 may calculate the RAF for the associated range of addresses 220. In some examples, the host system 205 may indicate a minimum quantity of read operations per range of addresses 220 for which to calculate the RAF (e.g., through setting one or more mode registers). The memory system 210 may calculate the RAF and may update the one or more status indicators. After updating the status indicators, the memory system 210 may modify the frequency of the refresh operations according to the updated status indicators (e.g., according to the RAF, as further described with reference to FIG. 6).

The use of an RAF may allow the memory system 210 to address memory block performance issues. For example, by triggering and modulating a rate of refreshes according to performance impact based on the RAF, the memory system 210 may take read attempts, idle time, and performance expectations into account. The use of an RAF may also be used in the management of other refresh and maintenance operations, which may simplify overall operations at the memory system 210 and increase efficiency of the system 200.

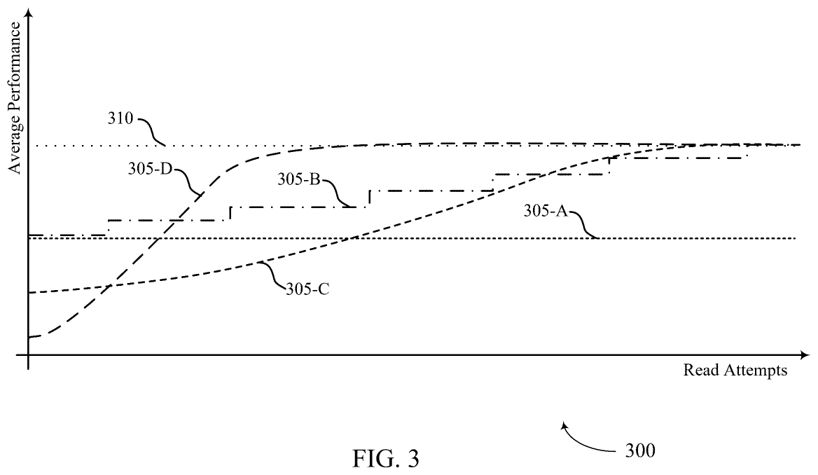

FIG. 3 shows an example of a performance graph 300 that supports refresh triggers to stabilize read operation performance in accordance with examples as disclosed herein. The performance graph 300 illustrates various refreshes 305 in relation to an average performance of a memory system (e.g., as described herein) and read attempts made by the memory system. For example, the performance graph 300 includes average performance of the memory system along the y-axis and quantity of read attempts by the memory system along the x-axis. The performance graph 300 also includes a baseline 310 that may be an example of a point at which each of the refreshes 305 may be complete.

To account for additional refresh operations, a memory system may implement the use of an RAF to estimate a rate between an actual quantity of read operations performed and an ideal (e.g., or theoretical) quantity of read operations used to complete read commands. For example, a memory system may determine an RAF for a range of memory addresses. Based on the RAF (e.g., or status indicators associated with the RAF), the memory system may modify a frequency of performing refresh operations on the range of memory addresses to better account for potential errors in the stored data and thereby reduce read retries for future read commands. The memory system may determine, via comparing the RAF with one or more thresholds, that the frequency at which the memory system performs refresh operations may be increased or decreased to improve performance of the memory system.

A first line 305-a may illustrate performance of a memory system if no additional refresh operations are performed. Memory systems perform refresh operations on a schedule to ensure that data is retained. As a memory system ages, memory cells may wear out and thus reduce the data retention time of memory cells. These techniques are about dynamically increasing the rate of refresh. If additional refreshes are not performed (relative to a base refresh rate), then the first line 305-a shows a steady performance. In some cases, this performance is below expectations for the memory system. In some cases, this performance may decrease overtime.

A second line 305-b may illustrate performance of a memory system if some additional refresh operations are performed during background operations (e.g., a lower priority for refreshes). In some examples, the memory system may determine the RAF to be greater than the first threshold and less than a second threshold (e.g., between the first and second thresholds), which may indicate that a refresh may not be urgent and may be executed during a background operation. In the case that the memory system performs additional refresh operations (e.g., increases the refresh rate) during background operation, the performance of the memory system may improve during idle times. Thus, performance may improve in a step-wise manner during idle time of the memory system.

A third line 305-c may illustrate performance of a memory system if some additional refresh operations are performed during some foreground operations (e.g., a higher priority for refreshes). In some examples, the memory system may determine the RAF to be greater than the second threshold and less than a third threshold (e.g., between the second and third thresholds), which may indicate that a refresh may may be performed during some foreground operations (such as a write operation). In the case that the memory system performs additional refresh operations (e.g., increases the refresh rate) during some foreground operations, the read performance of the memory system may increase more quickly than what is shown by the second line 305-b.

A fourth line 305-d may illustrate performance of a memory system if foreground operations are interrupted to immediately perform one or more additional refresh operations (e.g., a highest priority for refreshes). In some examples, the memory system may determine the RAF to be greater than the third threshold (e.g., greater than all thresholds), which may indicate that a refresh may be urgent due to high performance impact and should be immediately performed. In the case that the memory system may interrupt foreground operations (e.g., write operations and/or read operations) to perform additional refresh operations. The read performance of the memory system may increase more quickly than what is shown by the third line 305-c.

Using an RAF to distinguish how to dynamically adjust a refresh rate may allow the memory system to improve its read performance. For example, the use of an RAF may allow the memory system to estimate overhead added in performing read operations associated with refresh operations, which may enable the memory system to address errors in memory block while mitigating decreases in read operations and performance.

FIG. 4 shows an example of a process flow 400 that supports refresh triggers to stabilize read operation performance in accordance with examples as disclosed herein. The operations of process flow 400 may be performed by a memory system, a host system, or one or more controllers thereof as described herein. For example, the process flow 400 may illustrate exchanges of commands and data associated with triggering and managing various maintenance operations between a memory system 210-a and a host system 205-a, which may represent examples of corresponding systems as described with reference to FIGS. 1, 2, and 3.

At 405, capabilities of the memory system 210-a may be determined. For example, the host system may determine whether the memory system 210-a is capable of determining an RAF and/or using the RAF to determine rates of the refresh operations. In the case that the memory system 210-a may support using an RAF, the host system 205-a may transmit one or more commands associated with the RAF to the memory system 210-a. In the case that the memory system 210-a may not support using an RAF, the host system 205-a may not transmit one or more commands associated with the RAF.

At 410, a command indicating a range of addresses may be communicated. For example, the host system 205-a may transmit, and the memory system 210-a may receive, a command indicating a range of addresses at the memory system 210-a over which an RAF may be determined. The host system 205-a may transmit the address range indication in response to determining the memory system 210-a is capable of using an RAF. In some examples, the command indicating the range of addresses at the memory system 210-a may indicate multiple ranges of addresses and a quantity of addresses associated with each respective address range. For example, the range of addresses at the memory system 210-a over which an RAF may be determined may be associated with a range of the multiple indicated ranges. The RAF may be an example of a ratio of a first rate and a second rate, where the first rate may be associated with a quantity of read operations performed at the memory system 210-a on the indicated range of addresses over a duration (e.g., a real rate, an actual rate) and the second rate may be associated with a minimum quantity of read operations capable of being performed by the memory system 210-a on the range of addresses over the same duration (e.g., a theoretical rate).

At 415, an RAF availability indication may be communicated. For example, the memory system 210-a may transmit an indication that the RAF may be available (e.g., determined, calculated) to the host system 205-a. In some cases, RAFs calculated by the memory system 210-a may be stored in one or more memory registers. The availability indication may be a signal to inform the host that RAF information is stored in one or more registers.

At 420, an output command may be communicated. For example, the host system 205-a may transmit a command to output the RAF (e.g., or one or more status indicators associated with the RAF) associated with the range of addresses to the memory system 210-a. The host system 205-a may transmit the output command to the memory system 210-a in response to receiving the indication that the RAF may be available, and after transmitting the command including the address range indication. In some cases, the host system 205-a may periodically poll the registers that store that RAF information. In such cases, the availability indication may not be communicated.

At 425, a frequency of refresh operations at the memory system 210-a may be modified. For example, the host system 205-a may modify a frequency (e.g., of the memory system 210-a) of performing refresh operations on the range of addresses based on the RAF satisfying a threshold. In some examples, the host system 205-a modifying the frequency of refresh operations at the memory system 210-a may include transmitting a command to the memory system 210-a to schedule one or more refresh operations on the ranges addresses. In other examples, the host system 205-a modifying the frequency of refresh operations at the memory system 210-a may include transmitting a command to the memory system 210-a instructing the memory system 210-a to modify the frequency of refresh operations.

FIG. 5 shows an example of a process flow 500 that supports refresh triggers to stabilize read operation performance in accordance with examples as disclosed herein. The operations of process flow 500 may be performed by a memory system, a host system, or one or more controllers thereof as described herein. For example, the process flow 500 may illustrate exchanges of commands and data associated with triggering and managing various maintenance operations between a memory system 210-b and a host system 205-b, which may represent examples of corresponding systems as described with reference to FIGS. 1, 2, and 3.

At 505, a command indicating a range of addresses may be communicated. For example, the host system 205-b may transmit, and the memory system 210-b may receive, a command indicating a range of addresses at the memory system 210-b over which an RAF may be determined. In some examples, the command indicating the range of addresses at the memory system 210-b may indicate multiple ranges of addresses and a quantity of addresses associated with each respective address range. For example, the range of addresses at the memory system 210-b over which an RAF may be determined may be associated with a range of the multiple indicated ranges.

At 510, an RAF may be determined. For example, based on receiving the command indicating the range of addresses, the memory system 210-b may determine an RAF based on the range of addresses. The memory system 210-b may determine a first rate associated with a quantity of read operations performed by the memory system 210-b on the indicated range of addresses over a duration (e.g., a real rate, an actual rate). The memory system 210-b may also determine a second rate associated with a minimum quantity of read operations capable of being performed by the memory system 210-b on the range of addresses over the same duration (e.g., a theoretical rate). The duration may be associated with one or more read operations performed by the memory system 210-b to determine a priority of refresh operations at the range of addresses of the memory system. The memory system 210-b may determine the RAF by calculating (e.g., determining, taking) a ratio of the first rate and the second rate.

At 515, one or more status indicators may be updated. For example, the memory system 210-b may update one or more status indicators associated with the RAF (e.g., associated with refresh operations and the range of addresses) based on determining the RAF. The status indicators may be stored in one or more registers. In some cases, the host system 205-b may poll the registers that store the one or more status indicators. A poll may include sending an output command (e.g., at 525) to read the various registers. In other cases, the memory system 210-b may send an indication (e.g., at 520) that the one or more status indicators have been updated to the host system 205-b. In such cases, the host system 205-b may send the output command (e.g., at 525) in response to the indication.

At 520, a read factor determination indication may be communicated. For example, the memory system 210-b may transmit a status indicator to the host system 205-b indicating that the RAF has been determined.

At 525, an output command may be communicated. For example, the host system 205-b may transmit a command to output one or more status indicators associated with the RAF to the memory system 210-b. The host system 205-b may transmit the output command to the memory system 210-b in response to the memory system 210-b updating the one or more indicators associated with the RAF.

At 530, one or more status indicators may be communicated. For example, in response to receiving the output command, the memory system 210-b may output (e.g., transmit) one or more of the updated status indicators associated with the RAF to the host system 205-b.

At 535, a frequency of refresh operations at the memory system 210-b may be modified. For example, the memory system 210-b may determine whether the RAF satisfies a threshold. Based on the RAF satisfying a threshold, the memory system 210-b may modify a frequency of performing refresh operations on the range of addresses. The memory system 210-b may modify the frequency based on outputting the one or more status identifiers, based on outputting the read factor determination indication, or a combination thereof.

The memory system may modify the frequency according to a priority (e.g., an urgency). In some examples, modifying the frequency may include the memory system 210-b delaying the refresh operations on the range of addresses based on one of the status indicators indicating that the refresh operations may be associated with a lowest priority (e.g., a priority lower than other priorities). In some examples, modifying the frequency may include the memory system 210-b performing the refresh operations on the range of addresses during an idle mode of the memory system 210-b based on one of the status indicators indicating that the refresh operations are associated with a low priority (e.g., a priority higher than the lowest priority). In some examples, modifying the frequency may include the memory system 210-b performing one or more refresh operations on the range of addresses during an active mode of the memory system 210-b based on one of the status indicators indicating that the refresh operations are associated with a high priority (e.g., a priority higher than the lowest priority and the low priority). In some examples, modifying the frequency may include the memory system 210-b initiating performance of the one or more refresh operations on the range of addresses (e.g., immediately performing) based on one of the status indicators indicating that the refresh operations are associated with a highest priority (e.g., a priority higher than other priorities).

FIG. 6 shows an example of a process flow 600 that supports refresh triggers to stabilize read operation performance in accordance with examples as disclosed herein. The operations of process flow 600 may be performed by a memory system and/or a host system as described herein. For example, the process flow 600 may illustrate exchanges of commands and data associated with triggering and managing various maintenance operations at a memory system, which may represent an example of corresponding systems as described with reference to FIGS. 1, 2, and 3.

At 605, a process may begin. For example, a memory system and/or a host system may begin a process associated with triggering and managing refresh operations at the memory system.

At 610, a RAF may be determined. For example, the memory system and/or the host system may determine an RAF based on a range of addresses at the memory system. In some examples, the memory system may determine the RAF based on one or more read counts associated with the range of addresses. The memory system and/or the host system may determine a first rate associated with a quantity of read operations performed by the memory system on the indicated range of addresses over a duration (e.g., a real rate, an actual rate). The memory system and/or the host system may also determine a second rate associated with a minimum quantity of read operations capable of being performed by the memory system on the range of addresses over the same duration (e.g., a theoretical rate). The duration may be associated with one or more read operations performed by the memory system to determine a priority of refresh operations at the range of addresses of the memory system. The memory system and/or the host system may determine the RAF by calculating (e.g., determining, taking) a ratio of the first rate and the second rate.

At 615, one or more status indicators may be updated. For example, the memory system and/or the host system may update one or more status indicators associated with the RAF (e.g., associated with refresh operations and the range of addresses) based on determining the RAF.

At 620, a frequency of refresh operations at the memory system may be modified. For example, the memory system and/or a host system may determine whether the RAF satisfies a threshold. Based on the RAF satisfying a threshold, the memory system and/or the host system may modify a frequency of performing refresh operations on the range of addresses. In some examples, the memory system and/or the host system may modify the frequency of refresh operations based on one or more of the updated status indicators indicating that the RAF satisfies the threshold.

The memory system and/or the host system may modify the frequency according to an urgency (e.g., a priority). In some examples, modifying the frequency may include the memory system delaying the refresh operations on the range of addresses based on one of the updated status indicators indicating that the refresh operations may be associated with a lowest urgency (e.g., a lower priority than other priorities). In some examples, modifying the frequency may include the memory system and/or the host system scheduling the refresh operations to be performed on the range of addresses during an idle mode of the memory system based on one of the status indicators indicating that the refresh operations are associated with a low urgency (e.g., a priority higher than the lowest priority, an urgency higher than the lowest urgency). In some examples, modifying the frequency may include the memory system and/or the host system scheduling the one or more refresh operations on the range of addresses to be performed during an active mode of the memory system based on one of the status indicators indicating that the refresh operations are associated with a high urgency (e.g., a priority higher than the lowest priority and the low priority, an urgency higher than the lowest and low urgencies). In some examples, modifying the frequency may include the memory system and/or the host system initiating performance of the one or more refresh operations on the range of addresses (e.g., immediately performing) based on one of the status indicators indicating that the refresh operations are associated with a highest urgency (e.g., a priority higher than other priorities, an urgency higher than other urgencies).

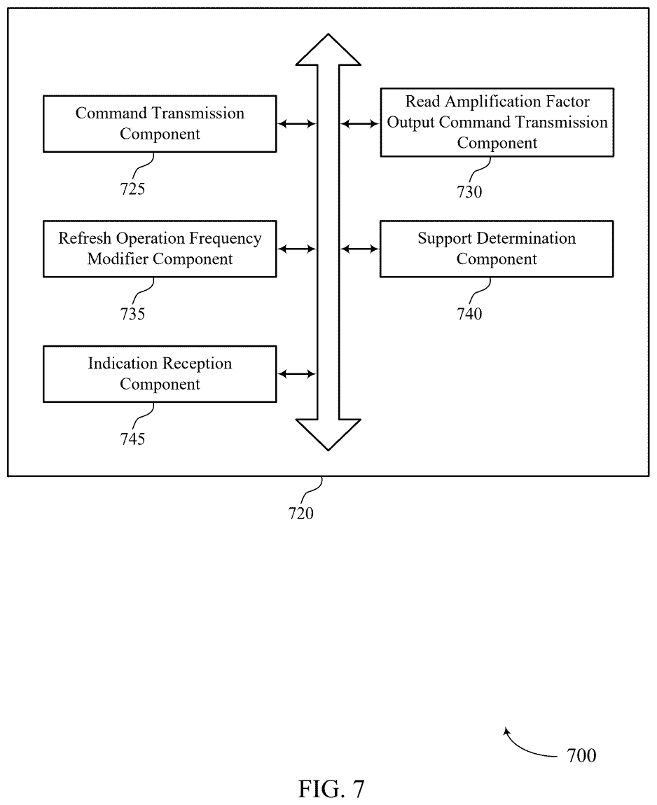

FIG. 7 shows a block diagram 700 of a host system 720 that supports refresh triggers to stabilize read operation performance in accordance with examples as disclosed herein. The host system 720 may be an example of aspects of a host system as described with reference to FIGS. 1 through 6. The host system 720, or various components thereof, may be an example of means for performing various aspects of refresh triggers to stabilize read operation performance as described herein. For example, the host system 720 may include a command transmission component 725, a read amplification factor output command transmission component 730, a refresh operation frequency modifier component 735, a support determination component 740, an indication reception component 745, or any combination thereof. Each of these components, or components of subcomponents thereof (e.g., one or more processors, one or more memories), may communicate, directly or indirectly, with one another (e.g., via one or more buses).

The command transmission component 725 may be configured as or otherwise support a means for transmitting a first command indicating a range of addresses at a memory system over which a read amplification factor is determined. The read amplification factor output command transmission component 730 may be configured as or otherwise support a means for transmitting a second command to output the read amplification factor associated with the range of addresses after transmitting the first command. The refresh operation frequency modifier component 735 may be configured as or otherwise support a means for modifying a frequency of performing refresh operations on the range of addresses based at least in part on the read amplification factor satisfying a threshold.

In some examples, the support determination component 740 may be configured as or otherwise support a means for determining whether the memory system supports using the read amplification factor to determine rates of the refresh operations, where transmitting the first command is based at least in part on the memory system supporting the use of the read amplification factor.

In some examples, to support modifying the frequency of performing the refresh operations, the command transmission component 725 may be configured as or otherwise support a means for transmitting a third command to schedule the refresh operations on the range of addresses.

In some examples, to support modifying the frequency of performing the refresh operations, the command transmission component 725 may be configured as or otherwise support a means for transmitting a third command instructing the memory system to modify the frequency of performing the refresh operations on the range of addresses.

In some examples, to support modifying the frequency of performing the refresh operations, the first rate includes a first quantity of read operations performed by the memory system on the range of addresses over a first duration of time, and the second rate includes a minimum quantity of read operations capable of being performed by the memory system on the range of addresses over the first duration of time.

In some examples, the indication reception component 745 may be configured as or otherwise support a means for receiving an indication that the read amplification factor is available, where transmitting the second command to output the read amplification factor associated with the range of addresses is based at least in part on receiving the indication.

In some examples, the first command indicates a plurality of ranges of addresses and a quantity of addresses associated with each respective range. In some examples, the range of addresses at the memory system over which the read amplification factor is determined corresponds to a range of the plurality of ranges of addresses.

In some examples, the described functionality of the host system 720, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the host system 720, or various components thereof, may be implemented at least in part by instructions (e.g., stored in memory, non-transitory computer-readable medium) executable by such at least one processor.

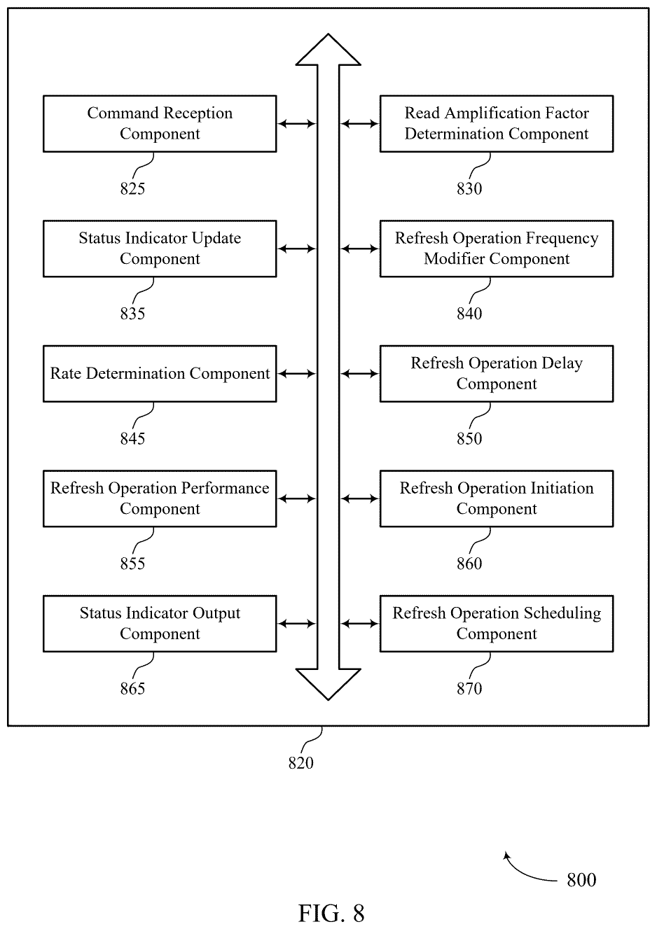

FIG. 8 shows a block diagram 800 of a memory system 820 that supports refresh triggers to stabilize read operation performance in accordance with examples as disclosed herein. The memory system 820 may be an example of aspects of a memory system as described with reference to FIGS. 1 through 6. The memory system 820, or various components thereof, may be an example of means for performing various aspects of refresh triggers to stabilize read operation performance as described herein. For example, the memory system 820 may include a command reception component 825, a read amplification factor determination component 830, a status indicator update component 835, a refresh operation frequency modifier component 840, a rate determination component 845, a refresh operation delay component 850, a refresh operation performance component 855, a refresh operation initiation component 860, a status indicator output component 865, a refresh operation scheduling component 870, or any combination thereof. Each of these components, or components of subcomponents thereof (e.g., one or more processors, one or more memories), may communicate, directly or indirectly, with one another (e.g., via one or more buses).

The command reception component 825 may be configured as or otherwise support a means for receiving a first command indicating a range of addresses at the memory system. The read amplification factor determination component 830 may be configured as or otherwise support a means for determining a read amplification factor associated with the range of addresses based at least in part on receiving the first command. The status indicator update component 835 may be configured as or otherwise support a means for updating one or more status indicators associated with the read amplification factor based at least in part on determining the read amplification factor. The refresh operation frequency modifier component 840 may be configured as or otherwise support a means for modifying a frequency of performing refresh operations on the range of addresses based at least in part on the read amplification factor satisfying a threshold.

In some examples, to support determining the read amplification factor, the rate determination component 845 may be configured as or otherwise support a means for determining a first rate associated with a first quantity of read operations performed by the memory system on the range of addresses over a first duration of time. In some examples, to support determining the read amplification factor, the rate determination component 845 may be configured as or otherwise support a means for determining a second rate associated with a minimum quantity of read operations capable of being performed by the memory system on the range of addresses over the first duration of time.

In some examples, the read amplification factor includes a ratio of the first rate and the second rate.

In some examples, to support modifying the frequency of performing the refresh operations, the refresh operation delay component 850 may be configured as or otherwise support a means for delaying the refresh operations on the range of addresses based at least in part on a first status indicator of the one or more status indicators indicating that the refresh operations are associated with a first priority.

In some examples, to support modifying the frequency of performing the refresh operations, the refresh operation performance component 855 may be configured as or otherwise support a means for performing the refresh operations on the range of addresses during an idle mode of the memory system based at least in part on a first status indicator of the one or more status indicators indicating that the refresh operations are associated with a second priority.

In some examples, to support modifying the frequency of performing the refresh operations, the refresh operation performance component 855 may be configured as or otherwise support a means for performing one or more refresh operations on the range of addresses during an active mode of the memory system based at least in part on a first status indicator of the one or more status indicators indicating that the refresh operations are associated with a third priority.

In some examples, to support modifying the frequency of performing the refresh operations, the refresh operation initiation component 860 may be configured as or otherwise support a means for initiating the refresh operations on the range of addresses based at least in part on a first status indicator of the one or more status indicators indicating that the refresh operations are associated with a fourth priority.

In some examples, the command reception component 825 may be configured as or otherwise support a means for receiving a second command to output the one or more status indicators associated with the read amplification factor based at least in part on updating the one or more status indicators associated with the read amplification factor. In some examples, the status indicator output component 865 may be configured as or otherwise support a means for outputting the one or more status indicators associated with the read amplification factor based at least in part on receiving the second command, where modifying the frequency of performing refresh operations is based at least in part on outputting the one or more status indicators.

In some examples, the status indicator output component 865 may be configured as or otherwise support a means for outputting a second status indicator of the updated one or more status indicators indicating that the read amplification factor has been determined, where modifying the frequency of performing the refresh operations on the range of addresses based at least in part on outputting the second status indicator.

In some examples, the read amplification factor determination component 830 may be configured as or otherwise support a means for determining a read amplification factor for a range of addresses of the memory system based on one or more read counts associated with the range of addresses. In some examples, the status indicator update component 835 may be configured as or otherwise support a means for updating one or more status indicators associated with the read amplification factor based at least in part on determining the read amplification factor. In some examples, the refresh operation frequency modifier component 840 may be configured as or otherwise support a means for modifying a frequency of performing refresh operations on the range of addresses based at least in part on a first status indicator of the updated one or more status indicators indicating that the read amplification factor satisfies a threshold.

In some examples, to support determining the read amplification factor, the rate determination component 845 may be configured as or otherwise support a means for determining a first rate associated with a first quantity of operations over a first duration of time. In some examples, to support determining the read amplification factor, the rate determination component 845 may be configured as or otherwise support a means for determining a second rate associated with a second quantity of operations over a second duration of time, where the second quantity of operations includes a minimum quantity of read operations required for the refresh operations.

In some examples, the read amplification factor includes a ratio of the first rate and the second rate.

In some examples, to support modifying the frequency of performing the refresh operations, the refresh operation delay component 850 may be configured as or otherwise support a means for delaying the refresh operations on the range of addresses based at least in part on the first status indicator indicating that the refresh operations are associated with a lowest urgency.

In some examples, to support modifying the frequency of performing the refresh operations, the refresh operation scheduling component 870 may be configured as or otherwise support a means for scheduling the refresh operations on the range of addresses for performance during an idle mode of the memory system based at least in part on the first status indicator indicating that the refresh operations are associated with a low urgency.

In some examples, to support modifying the frequency of performing the refresh operations, the refresh operation scheduling component 870 may be configured as or otherwise support a means for scheduling the refresh operations on the range of addresses for performance during an active mode of the memory system based at least in part on the first status indicator indicating that the refresh operations are associated with a high urgency.

In some examples, to support modifying the frequency of performing the refresh operations, the refresh operation initiation component 860 may be configured as or otherwise support a means for initiating the refresh operations on the range of addresses based at least in part on the first status indicator indicating that the refresh operations are associated with a highest urgency.

In some examples, to support modifying the frequency of performing the refresh operations, the refresh operation frequency modifier component 840 may be configured as or otherwise support a means for modifying the frequency of performing the refresh operations on the range of addresses according to a priority level.

In some examples, the described functionality of the memory system 820, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 820, or various components thereof, may be implemented at least in part by instructions (e.g., stored in memory, non-transitory computer-readable medium) executable by such at least one processor.

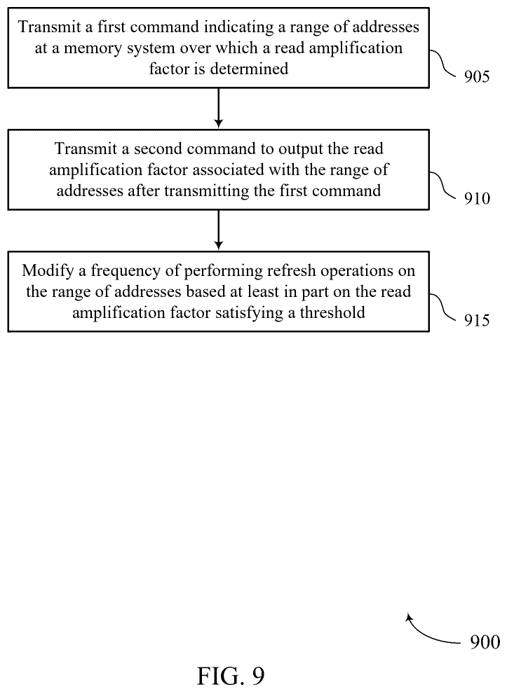

FIG. 9 shows a flowchart illustrating a method 900 that supports refresh triggers to stabilize read operation performance in accordance with examples as disclosed herein. The operations of method 900 may be implemented by a host system or its components as described herein. For example, the operations of method 900 may be performed by a host system as described with reference to FIGS. 1 through 7. In some examples, a host system may execute a set of instructions to control the functional elements of the device to perform the described functions. Additionally, or alternatively, the host system may perform aspects of the described functions using special-purpose hardware.

At 905, the method may include transmitting a first command indicating a range of addresses at a memory system over which a read amplification factor is determined. In some examples, aspects of the operations of 905 may be performed by a command transmission component 725 as described with reference to FIG. 7.

At 910, the method may include transmitting a second command to output the read amplification factor associated with the range of addresses after transmitting the first command. In some examples, aspects of the operations of 910 may be performed by a read amplification factor output command transmission component 730 as described with reference to FIG. 7.

At 915, the method may include modifying a frequency of performing refresh operations on the range of addresses based at least in part on the read amplification factor satisfying a threshold. In some examples, aspects of the operations of 915 may be performed by a refresh operation frequency modifier component 735 as described with reference to FIG. 7.

In some examples, an apparatus as described herein may perform a method or methods, such as the method 900. The apparatus may include features, circuitry, logic, means, or instructions (e.g., a non-transitory computer-readable medium storing instructions executable by a processor), or any combination thereof for performing the following aspects of the present disclosure:
Aspect 1: A method, apparatus, or non-transitory computer-readable medium including operations, features, circuitry, logic, means, or instructions, or any combination thereof for transmitting a first command indicating a range of addresses at a memory system over which a read amplification factor is determined; transmitting a second command to output the read amplification factor associated with the range of addresses after transmitting the first command; and modifying a frequency of performing refresh operations on the range of addresses based at least in part on the read amplification factor satisfying a threshold.
Aspect 2: The method, apparatus, or non-transitory computer-readable medium of aspect 1, further including operations, features, circuitry, logic, means, or instructions, or any combination thereof for determining whether the memory system supports using the read amplification factor to determine rates of the refresh operations, where transmitting the first command is based at least in part on the memory system supporting the use of the read amplification factor.
Aspect 3: The method, apparatus, or non-transitory computer-readable medium of any of aspects 1 through 2, where modifying the frequency of performing the refresh operations further includes operations, features, circuitry, logic, means, or instructions, or any combination thereof for transmitting a third command to schedule the refresh operations on the range of addresses.
Aspect 4: The method, apparatus, or non-transitory computer-readable medium of any of aspects 1 through 3, where modifying the frequency of performing the refresh operations further includes operations, features, circuitry, logic, means, or instructions, or any combination thereof for transmitting a third command instructing the memory system to modify the frequency of performing the refresh operations on the range of addresses.
Aspect 5: The method, apparatus, or non-transitory computer-readable medium of any of aspects 1 through 4, where the read amplification factor comprises a ratio of a first rate and a second rate. The first rate including a first quantity of read operations performed by the memory system on the range of addresses over a first duration of time. The second rate including a minimum quantity of read operations capable of being performed by the memory system on the range of addresses over the first duration of time.
Aspect 6: The method, apparatus, or non-transitory computer-readable medium of any of aspects 1 through 5, further including operations, features, circuitry, logic, means, or instructions, or any combination thereof for receiving an indication that the read amplification factor is available, where transmitting the second command to output the read amplification factor associated with the range of addresses is based at least in part on receiving the indication.
Aspect 7: The method, apparatus, or non-transitory computer-readable medium of any of aspects 1 through 6, where the first command indicates a plurality of ranges of addresses and a quantity of addresses associated with each respective range and the range of addresses at the memory system over which the read amplification factor is determined corresponds to a range of the plurality of ranges of addresses.

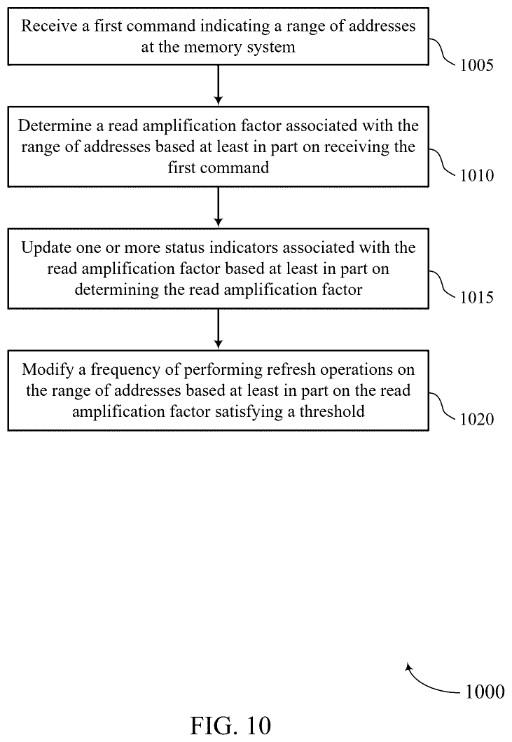

FIG. 10 shows a flowchart illustrating a method 1000 that supports refresh triggers to stabilize read operation performance in accordance with examples as disclosed herein. The operations of method 1000 may be implemented by a memory system or its components as described herein. For example, the operations of method 1000 may be performed by a memory system as described with reference to FIGS. 1 through 6 and 8. In some examples, a memory system may execute a set of instructions to control the functional elements of the device to perform the described functions. Additionally, or alternatively, the memory system may perform aspects of the described functions using special-purpose hardware.

At 1005, the method may include receiving a first command indicating a range of addresses at the memory system. In some examples, aspects of the operations of 1005 may be performed by a command reception component 825 as described with reference to FIG. 8.

At 1010, the method may include determining a read amplification factor associated with the range of addresses based at least in part on receiving the first command. In some examples, aspects of the operations of 1010 may be performed by a read amplification factor determination component 830 as described with reference to FIG. 8.

At 1015, the method may include updating one or more status indicators associated with the read amplification factor based at least in part on determining the read amplification factor. In some examples, aspects of the operations of 1015 may be performed by a status indicator update component 835 as described with reference to FIG. 8.

At 1020, the method may include modifying a frequency of performing refresh operations on the range of addresses based at least in part on the read amplification factor satisfying a threshold. In some examples, aspects of the operations of 1020 may be performed by a refresh operation frequency modifier component 840 as described with reference to FIG. 8.

In some examples, an apparatus as described herein may perform a method or methods, such as the method 1000. The apparatus may include features, circuitry, logic, means, or instructions (e.g., a non-transitory computer-readable medium storing instructions executable by a processor), or any combination thereof for performing the following aspects of the present disclosure:
Aspect 8: A method, apparatus, or non-transitory computer-readable medium including operations, features, circuitry, logic, means, or instructions, or any combination thereof for receiving a first command indicating a range of addresses at the memory system; determining a read amplification factor associated with the range of addresses based at least in part on receiving the first command; updating one or more status indicators associated with the read amplification factor based at least in part on determining the read amplification factor; and modifying a frequency of performing refresh operations on the range of addresses based at least in part on the read amplification factor satisfying a threshold.
Aspect 9: The method, apparatus, or non-transitory computer-readable medium of aspect 8, where determining the read amplification factor further includes operations, features, circuitry, logic, means, or instructions, or any combination thereof for determining a first rate associated with a first quantity of read operations performed by the memory system on the range of addresses over a first duration of time, and determining a second rate associated with a minimum quantity of read operations capable of being performed by the memory system on the range of addresses over the first duration of time.
Aspect 10: The method, apparatus, or non-transitory computer-readable medium of aspect 9, where the read amplification factor includes a ratio of the first rate and the second rate. The first rate including a first quantity of read operations performed by the memory system on the range of addresses over a first duration of time. The second rate including a minimum quantity of read operations capable of being performed by the memory system on the range of addresses over the first duration of time.
Aspect 11: The method, apparatus, or non-transitory computer-readable medium of any of aspects 8 through 10, where modifying the frequency of performing the refresh operations includes operations, features, circuitry, logic, means, or instructions, or any combination thereof for delaying the refresh operations on the range of addresses based at least in part on a first status indicator of the one or more status indicators indicating that the refresh operations are associated with a first priority.
Aspect 12: The method, apparatus, or non-transitory computer-readable medium of any of aspects 8 through 11, where modifying the frequency of performing the refresh operations includes operations, features, circuitry, logic, means, or instructions, or any combination thereof for performing the refresh operations on the range of addresses during an idle mode of the memory system based at least in part on a first status indicator of the one or more status indicators indicating that the refresh operations are associated with a second priority.
Aspect 13: The method, apparatus, or non-transitory computer-readable medium of any of aspects 8 through 12, where modifying the frequency of performing the refresh operations includes operations, features, circuitry, logic, means, or instructions, or any combination thereof for performing one or more refresh operations on the range of addresses during an active mode of the memory system based at least in part on a first status indicator of the one or more status indicators indicating that the refresh operations are associated with a third priority.
Aspect 14: The method, apparatus, or non-transitory computer-readable medium of any of aspects 8 through 13, where modifying the frequency of performing the refresh operations includes operations, features, circuitry, logic, means, or instructions, or any combination thereof for initiating the refresh operations on the range of addresses based at least in part on a first status indicator of the one or more status indicators indicating that the refresh operations are associated with a fourth priority.
Aspect 15: The method, apparatus, or non-transitory computer-readable medium of any of aspects 8 through 14, further including operations, features, circuitry, logic, means, or instructions, or any combination thereof for receiving a second command to output the one or more status indicators associated with the read amplification factor based at least in part on updating the one or more status indicators associated with the read amplification factor and outputting the one or more status indicators associated with the read amplification factor based at least in part on receiving the second command, where modifying the frequency of performing refresh operations is based at least in part on outputting the one or more status indicators.
Aspect 16: The method, apparatus, or non-transitory computer-readable medium of any of aspects 8 through 15, further including operations, features, circuitry, logic, means, or instructions, or any combination thereof for outputting a second status indicator of the updated one or more status indicators indicating that the read amplification factor has been determined, where modifying the frequency of performing the refresh operations on the range of addresses based at least in part on outputting the second status indicator.

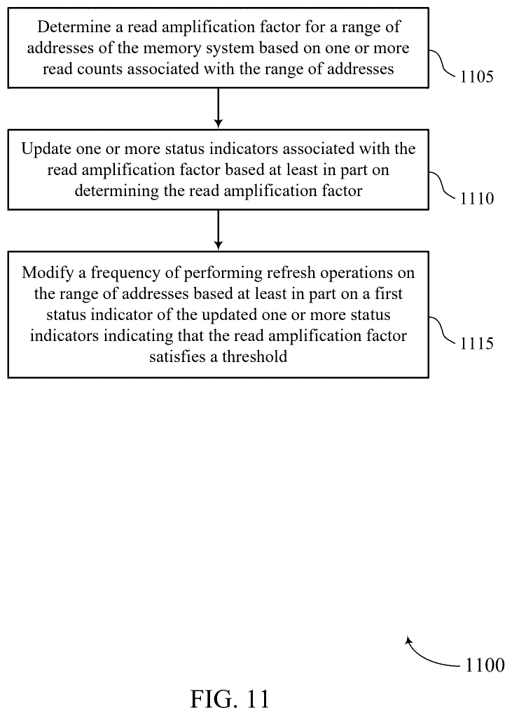

FIG. 11 shows a flowchart illustrating a method 1100 that supports refresh triggers to stabilize read operation performance in accordance with examples as disclosed herein. The operations of method 1100 may be implemented by a memory system or its components as described herein. For example, the operations of method 1100 may be performed by a memory system as described with reference to FIGS. 1 through 6 and 8. In some examples, a memory system may execute a set of instructions to control the functional elements of the device to perform the described functions. Additionally, or alternatively, the memory system may perform aspects of the described functions using special-purpose hardware.

At 1105, the method may include determining a read amplification factor for a range of addresses of the memory system based on one or more read counts associated with the range of addresses. In some examples, aspects of the operations of 1105 may be performed by a read amplification factor determination component 830 as described with reference to FIG. 8.

At 1110, the method may include updating one or more status indicators associated with the read amplification factor based at least in part on determining the read amplification factor. In some examples, aspects of the operations of 1110 may be performed by a status indicator update component 835 as described with reference to FIG. 8.

At 1115, the method may include modifying a frequency of performing refresh operations on the range of addresses based at least in part on a first status indicator of the updated one or more status indicators indicating that the read amplification factor satisfies a threshold. In some examples, aspects of the operations of 1115 may be performed by a refresh operation frequency modifier component 840 as described with reference to FIG. 8.

In some examples, an apparatus as described herein may perform a method or methods, such as the method 1100. The apparatus may include features, circuitry, logic, means, or instructions (e.g., a non-transitory computer-readable medium storing instructions executable by a processor), or any combination thereof for performing the following aspects of the present disclosure:
Aspect 17: A method, apparatus, or non-transitory computer-readable medium including operations, features, circuitry, logic, means, or instructions, or any combination thereof for determining a read amplification factor for a range of addresses of the memory system based on one or more read counts associated with the range of addresses; updating one or more status indicators associated with the read amplification factor based at least in part on determining the read amplification factor; and modifying a frequency of performing refresh operations on the range of addresses based at least in part on a first status indicator of the updated one or more status indicators indicating that the read amplification factor satisfies a threshold.
Aspect 18: The method, apparatus, or non-transitory computer-readable medium of aspect 17, where determining the read amplification factor further includes operations, features, circuitry, logic, means, or instructions, or any combination thereof for determining a first rate associated with a first quantity of operations over a first duration of time, and determining a second rate associated with a second quantity of operations over a second duration of time, where the second quantity of operations includes a minimum quantity of read operations required for the refresh operations.
Aspect 19: The method, apparatus, or non-transitory computer-readable medium of aspect 18, where the read amplification factor includes a ratio of the first rate and the second rate. The first rate including a first quantity of read operations performed by the memory system on the range of addresses over a first duration of time. The second rate including a minimum quantity of read operations capable of being performed by the memory system on the range of addresses over the first duration of time.
Aspect 20: The method, apparatus, or non-transitory computer-readable medium of any of aspects 17 through 19, where modifying the frequency of performing the refresh operations includes operations, features, circuitry, logic, means, or instructions, or any combination thereof for delaying the refresh operations on the range of addresses based at least in part on the first status indicator indicating that the refresh operations are associated with a lowest urgency.
Aspect 21: The method, apparatus, or non-transitory computer-readable medium of any of aspects 17 through 20, where modifying the frequency of performing the refresh operations includes operations, features, circuitry, logic, means, or instructions, or any combination thereof for scheduling the refresh operations on the range of addresses for performance during an idle mode of the memory system based at least in part on the first status indicator indicating that the refresh operations are associated with a low urgency.
Aspect 22: The method, apparatus, or non-transitory computer-readable medium of any of aspects 17 through 21, where modifying the frequency of performing the refresh operations includes operations, features, circuitry, logic, means, or instructions, or any combination thereof for scheduling the refresh operations on the range of addresses for performance during an active mode of the memory system based at least in part on the first status indicator indicating that the refresh operations are associated with a high urgency.
Aspect 23: The method, apparatus, or non-transitory computer-readable medium of any of aspects 17 through 22, where modifying the frequency of performing the refresh operations includes operations, features, circuitry, logic, means, or instructions, or any combination thereof for initiating the refresh operations on the range of addresses based at least in part on the first status indicator indicating that the refresh operations are associated with a highest urgency.
Aspect 24: The method, apparatus, or non-transitory computer-readable medium of any of aspects 17 through 23, where modifying the frequency of performing the refresh operations includes operations, features, circuitry, logic, means, or instructions, or any combination thereof for modifying the frequency of performing the refresh operations on the range of addresses according to a priority level.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A host system, comprising:
one or more interfaces comprising one or more signal paths operable for communications with one or more memory systems; and
processing circuitry coupled with the one or more interfaces and configured to cause the host system to:
transmit a first command indicating a range of addresses at a memory system over which a read amplification factor is determined;
transmit a second command to output the read amplification factor associated with the range of addresses after transmitting the first command; and
modify a frequency of performing refresh operations on the range of addresses based at least in part on the read amplification factor satisfying a threshold.

2. The host system of claim 1, wherein the processing circuitry is further configured to cause the host system to:
determine whether the memory system supports using the read amplification factor to determine rates of the refresh operations, wherein transmitting the first command is based at least in part on the memory system supporting the use of the read amplification factor.

3. The host system of claim 1, wherein modifying the frequency of performing the refresh operations further comprises the processing circuitry configured to cause the host system to:
transmit a third command to schedule the refresh operations on the range of addresses.

4. The host system of claim 1, wherein modifying the frequency of performing the refresh operations further comprises the processing circuitry configured to cause the host system to:
transmit a third command instructing the memory system to modify the frequency of performing the refresh operations on the range of addresses.

5. The host system of claim 1, wherein the read amplification factor comprises a ratio of a first rate and a second rate, the first rate comprising a first quantity of read operations performed by the memory system on the range of addresses over a first duration of time, and the second rate comprising a minimum quantity of read operations capable of being performed by the memory system on the range of addresses over the first duration of time.

6. The host system of claim 1, wherein the processing circuitry is further configured to cause the host system to:
receive an indication that the read amplification factor is available, wherein transmitting the second command to output the read amplification factor associated with the range of addresses is based at least in part on receiving the indication.

7. The host system of claim 1, wherein:
the first command indicates a plurality of ranges of addresses and a quantity of addresses associated with each respective range, and
the range of addresses at the memory system over which the read amplification factor is determined corresponds to a range of the plurality of ranges of addresses.

8. A memory system, comprising:
one or more memory devices; and
processing circuitry coupled with the one or more memory devices and configured to cause the memory system to:
receive a first command indicating a range of addresses at the memory system;
determine a read amplification factor associated with the range of addresses based at least in part on receiving the first command;
update one or more status indicators associated with the read amplification factor based at least in part on determining the read amplification factor; and
modify a frequency of performing refresh operations on the range of addresses based at least in part on the read amplification factor satisfying a threshold.

9. The memory system of claim 8, wherein determining the read amplification factor further comprises the processing circuitry configured to cause the memory system to:
determine a first rate associated with a first quantity of read operations performed by the memory system on the range of addresses over a first duration of time; and
determine a second rate associated with a minimum quantity of read operations capable of being performed by the memory system on the range of addresses over the first duration of time.

10. The memory system of claim 9, wherein the read amplification factor comprises a ratio of the first rate and the second rate.

11. The memory system of claim 8, wherein modifying the frequency of performing the refresh operations comprises the processing circuitry configured to cause the memory system to:
delay the refresh operations on the range of addresses based at least in part on a first status indicator of the one or more status indicators indicating that the refresh operations are associated with a first priority.

12. The memory system of claim 8, wherein modifying the frequency of performing the refresh operations comprises the processing circuitry configured to cause the memory system to:
perform the refresh operations on the range of addresses during an idle mode of the memory system based at least in part on a first status indicator of the one or more status indicators indicating that the refresh operations are associated with a second priority.

13. The memory system of claim 8, wherein modifying the frequency of performing the refresh operations comprises the processing circuitry configured to cause the memory system to:
perform one or more refresh operations on the range of addresses during an active mode of the memory system based at least in part on a first status indicator of the one or more status indicators indicating that the refresh operations are associated with a third priority.

14. The memory system of claim 8, wherein modifying the frequency of performing the refresh operations comprises the processing circuitry configured to cause the memory system to:
initiate the refresh operations on the range of addresses based at least in part on a first status indicator of the one or more status indicators indicating that the refresh operations are associated with a fourth priority.

15. The memory system of claim 8, wherein the processing circuitry is further configured to cause the memory system to:
receive a second command to output the one or more status indicators associated with the read amplification factor based at least in part on updating the one or more status indicators associated with the read amplification factor; and
output the one or more status indicators associated with the read amplification factor based at least in part on receiving the second command, wherein modifying the frequency of performing refresh operations is based at least in part on outputting the one or more status indicators.

16. The memory system of claim 8, wherein the processing circuitry is further configured to cause the memory system to:
output a second status indicator of the updated one or more status indicators indicating that the read amplification factor has been determined, wherein modifying the frequency of performing the refresh operations on the range of addresses based at least in part on outputting the second status indicator.

17. A memory system, comprising:
one or more memory devices; and
processing circuitry coupled with the one or more memory devices and configured to cause the memory system to:
determine a read amplification factor for a range of addresses of the memory system based on one or more read counts associated with the range of addresses;
update one or more status indicators associated with the read amplification factor based at least in part on determining the read amplification factor; and
modify a frequency of performing refresh operations on the range of addresses based at least in part on a first status indicator of the updated one or more status indicators indicating that the read amplification factor satisfies a threshold.

18. The memory system of claim 17, wherein determining the read amplification factor further comprises the processing circuitry configured to cause the memory system to:
determine a first rate associated with a first quantity of operations over a first duration of time; and
determine a second rate associated with a second quantity of operations over a second duration of time, wherein the second quantity of operations comprises a minimum quantity of read operations required for the refresh operations.

19. The memory system of claim 18, wherein the read amplification factor comprises a ratio of the first rate and the second rate.

20. The memory system of claim 17, wherein modifying the frequency of performing the refresh operations comprises the processing circuitry configured to cause the memory system to:
delay the refresh operations on the range of addresses based at least in part on the first status indicator indicating that the refresh operations are associated with a lowest urgency.

21. The memory system of claim 17, wherein modifying the frequency of performing the refresh operations comprises the processing circuitry configured to cause the memory system to:
schedule the refresh operations on the range of addresses for performance during an idle mode of the memory system based at least in part on the first status indicator indicating that the refresh operations are associated with a low urgency.

22. The memory system of claim 17, wherein modifying the frequency of performing the refresh operations comprises the processing circuitry configured to cause the memory system to:
schedule the refresh operations on the range of addresses for performance during an active mode of the memory system based at least in part on the first status indicator indicating that the refresh operations are associated with a high urgency.

23. The memory system of claim 17, wherein modifying the frequency of performing the refresh operations comprises the processing circuitry configured to cause the memory system to:
initiate the refresh operations on the range of addresses based at least in part on the first status indicator indicating that the refresh operations are associated with a highest urgency.

24. The memory system of claim 17, wherein modifying the frequency of performing the refresh operations comprises the processing circuitry configured to cause the memory system to:
modify the frequency of performing the refresh operations on the range of addresses according to a priority level.
